(19) United States
(12) Patent Application Publication
(10) Pub. No.: US 2013/0278063 A1
(43) Pub. Date: Oct. 24, 2013

(54) SOLAR ENERGY COLLECTION, STORAGE AND POWER SUPPLY DEVICE

(71) Applicant: David Fowler, Dorchester (GB)

(72) Inventor: David Fowler, Dorchester (GB)

(73) Assignee: Better Energy Systems Inc.

(21) Appl. No.: 13/451,303

(22) Filed: Apr. 19, 2012

(51) Int. Cl. H02J 1/00; H01L 31/024

(52) U.S. Cl. 307/43; 136/259

(57) ABSTRACT

A solar energy collection, storage and power supply device includes an assembly having a photovoltaic element layer bonded to a heat sink with a plurality of fins and having an outer ledge extending therefrom. A hollow housing has one or more compartments therein, and the housing is coupled to the ledge and extends at least partially around the perimeter of the assembly. An energy storage system is provided within at least one compartment and a power supply system is provided within at least one compartment.

### FIELD

The present invention relates generally to the field of energy collection, storage and power supply devices. More specifically, the present invention relates to a solar energy collection, storage and power supply device having improved thermal performance and heat management features. Still more specifically, the present invention relates to a portable solar energy collection, storage and power supply device having a photovoltaic (PV) solar energy collection panel with an integral or conjoined heat sink and heat dissipation system, packaged within a housing having heat management features intended to minimize heat transfer between the solar panel and the energy storage and power supply components of the device.

### BACKGROUND

This section is intended to provide a background or context to the invention recited in the claims. The description herein may include concepts that could be pursued, but are not necessarily ones that have been previously conceived or pursued. Therefore, unless otherwise indicated herein, what is described in this section is not prior art to the description and claims in this application and is not admitted to be prior art by inclusion in this section.

It is generally well known to provide solar panels, such as PV panels in portable devices, to collect solar energy that charges a battery to provide electric power for consumption by the device, and/or to provide a source of electric power for other devices. However, such PV panels tend to generate heat to a degree that tends to reduce the electrical output of the PV panel, and thus reduces the performance and capacity of the device. Further, such known portable devices are often constructed in a manner that permits a relatively substantial amount of heat from the PV panel to be transferred to the battery and/or other power storage/supply components, thus degrading their capacity and/or reducing their effective operating life.

It would be desirable to provide a portable solar energy collection, storage and power supply device having a PV panel with improved heat management capability.

### SUMMARY

One embodiment of the invention relates to a portable solar energy collection, storage and power supply device. The device includes a housing, a power supply system within the housing, and an energy storage system within the housing and coupled to the power supply system. A solar energy collection and heat dissipation assembly is coupled to the housing and operably coupled to one or both of the energy storage system and the power supply system. The solar energy collection and heat dissipation assembly includes an upper transparent layer, a photovoltaic element layer bonded to the upper transparent layer by an upper adhesive layer, a heat sink having a base portion with an upper interface surface bonded to the photovoltaic element layer by a lower adhesive layer, where the base portion also includes a lower heat dissipation surface comprising a plurality of fins.

Another embodiment of the invention relates to a solar energy collection and heat dissipation device. The device includes a housing having an upper portion and a lower portion each having an opening therein. The upper portion has a lip surrounding the opening and the lower portion has a rim surrounding the opening. An assembly has a photovoltaic element layer bonded to a heat sink with a plurality of fins, and a ledge substantially surrounding the assembly, so that the assembly is provided within the opening with the ledge clamped between the lip and the rim.

Another embodiment of the invention relates to a solar energy collection and heat dissipation device. The device includes an assembly having a photovoltaic element layer bonded to a heat sink with a plurality of fins and having an outer ledge extending therefrom. A hollow housing has one or more compartments therein, and the housing is coupled to the ledge and extends at least partially around the perimeter of the assembly. An energy storage system is provided within at least one compartment and a power supply system is provided within at least one compartment.

### BRIEF DESCRIPTION OF THE DRAWINGS

The disclosure will become more fully understood from the following detailed description, taken in conjunction with the accompanying figures, wherein like reference numerals refer to like elements, in which:

FIG. 1 is a schematic representation of a top perspective view of a portable solar energy collection, storage and power supply device according to the exemplary embodiments described herein.

FIG. 2 is a schematic representation of a bottom perspective view of a portable solar energy collection, storage and power supply device according to the exemplary embodiments described herein.

FIG. 3 is a schematic representation of a top perspective cut-away view of a PV solar energy collection panel with an integral or conjoined heat sink and heat dissipation system according to the exemplary embodiment for use in the device shown in FIGS. 1 and 2.

FIG. 4 is a schematic representation of a bottom perspective view of the PV solar energy collection panel with an integral or conjoined heat sink and heat dissipation system according to the exemplary embodiment shown in FIG. 3.

FIG. 5 is a schematic representation of a cross sectional view of the PV solar energy collection panel with an integral or conjoined heat sink and heat dissipation system according to the exemplary embodiment in FIG. 3.

FIG. 6 is a schematic representation of a detailed cross sectional view of a portion of the PV solar energy collection panel with an integral or conjoined heat sink and heat dissipation system according to the exemplary embodiment for use in the device shown in FIG. 5.

FIG. 7 is a schematic representation of a perspective view of the PV solar energy collection panel with an integral or conjoined heat sink and heat dissipation system according to the exemplary embodiment shown in FIG. 1, with a top portion removed.

FIG. 8 is a schematic representation of a detailed cross sectional view of a portion of the PV solar energy collection panel with an integral or conjoined heat sink and heat dissipation system according to the exemplary embodiment shown in FIG. 1.

### DETAILED DESCRIPTION

Referring to the FIGURES, a portable solar energy collection, storage and power supply device having a PV solar energy collection panel with an integral or conjoined heat sink and heat dissipation system, packaged within a substantially hollow housing having heat management features to minimize heat transfer between the solar panel and the energy storage and power supply components of the device is shown according to exemplary embodiments. The embodiments of the device are shown to include multiple advantageous features for improving the thermal and electrical performance of portable solar devices by uniquely conjoining a heat sink and heat dissipation system to a back or bottom side of the PV panel, and packaging the PV panel within a uniquely designed housing structure that minimizes heat transfer from the PV panel and heat dissipation system to the energy storage and power supply components.

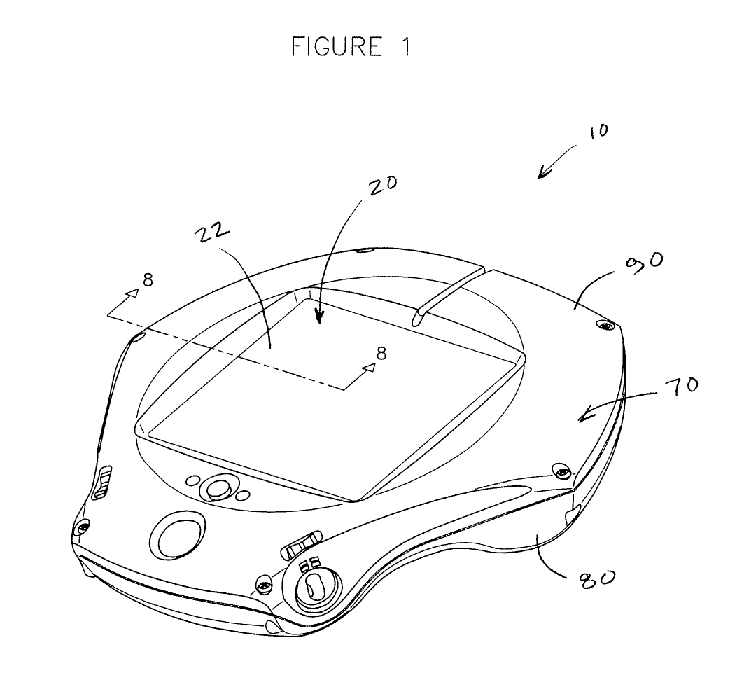

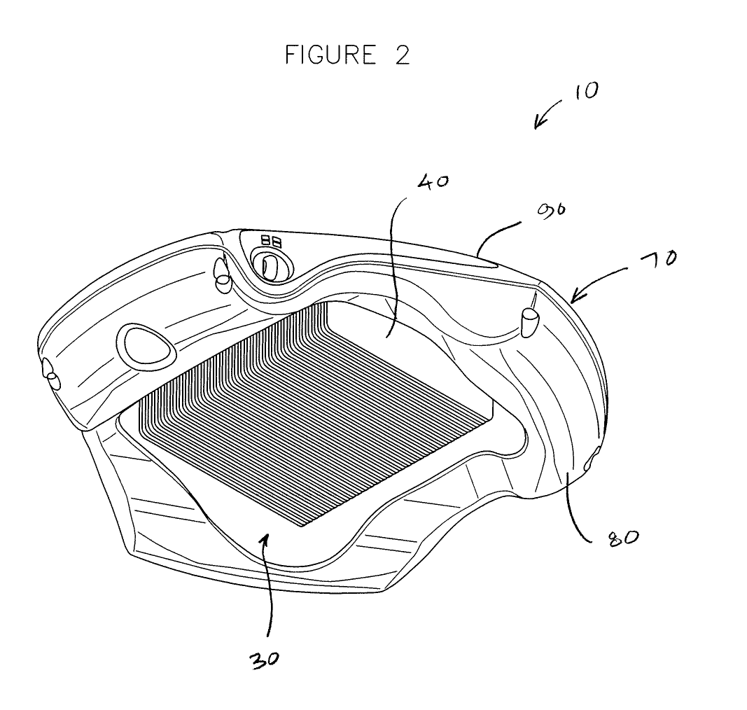

Referring more particularly to FIGS. 1 and 2, a portable solar energy collection, storage and power supply device 10 is shown according to an exemplary embodiment. Device 10 is shown to include a solar energy collection system 20 having a PV panel 22 with an integral or conjoined heat dissipation system 30 having a heat sink 32. Device 10 is also shown to include an energy storage system 50 having a battery(ies) 52, and suitable electronic components for charging the battery 52 with electrical energy generated by the PV panel 22 during exposure to sunlight. Device 10 is further shown to include a power supply system 60 having suitable electronic components configured to deliver electrical power to any of a wide variety of devices. The device 10 is also shown to include a substantially hollow housing 70 (e.g. casing, etc.) that has compartments which package therein the energy storage system and the power supply system, and at least partially surrounds and supports the PV panel and heat sink and heat dissipation system, in an arrangement intended to minimize heat transfer to the temperature-sensitive components of the energy storage system and power supply system of the device.

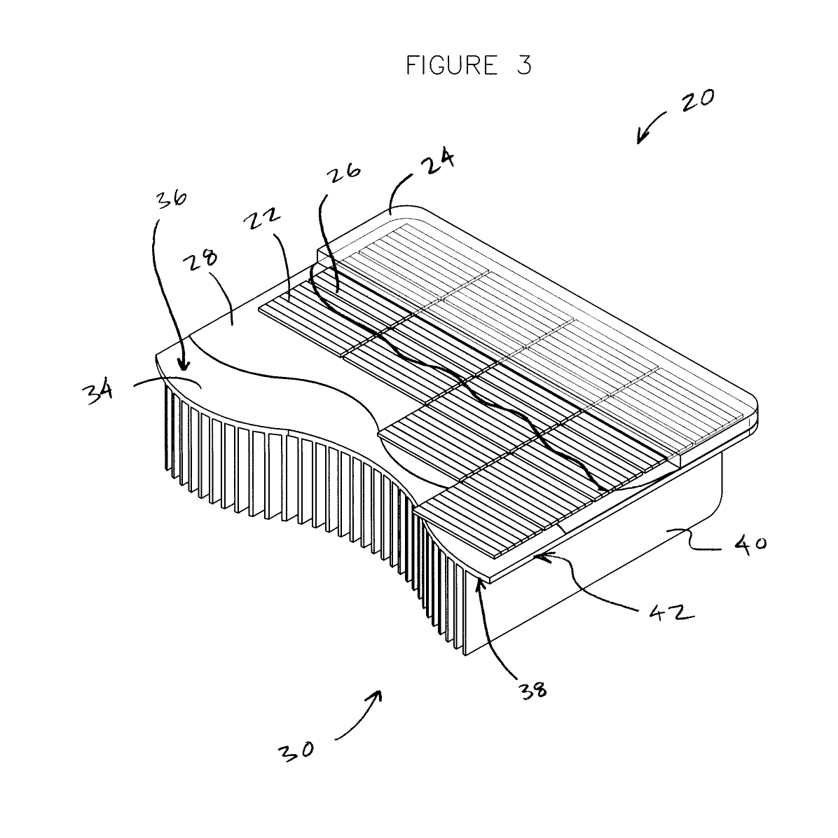

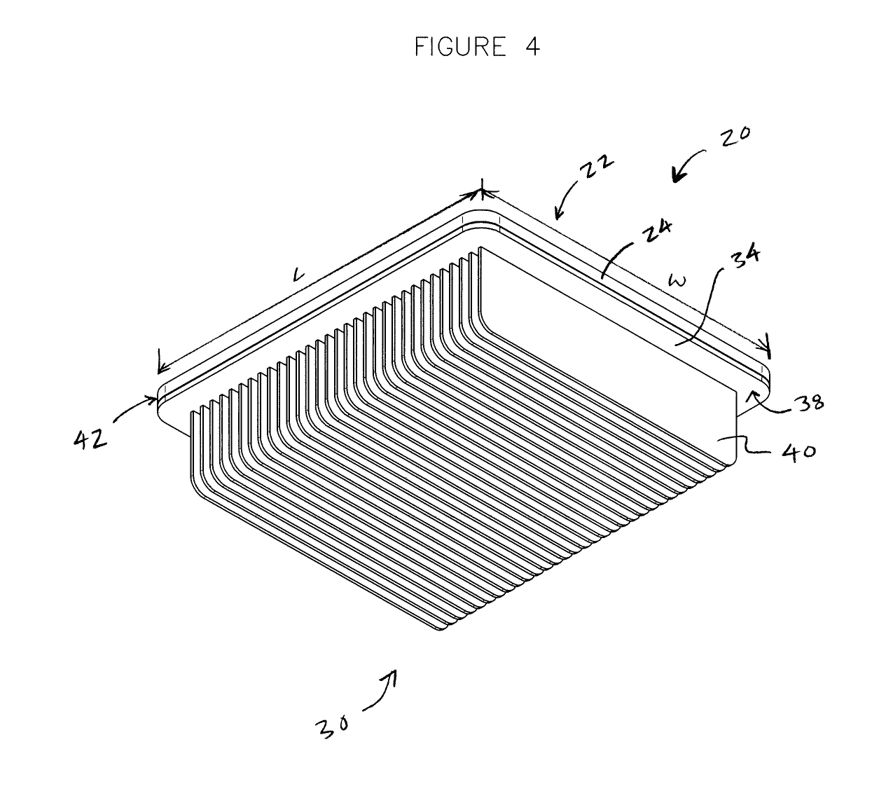

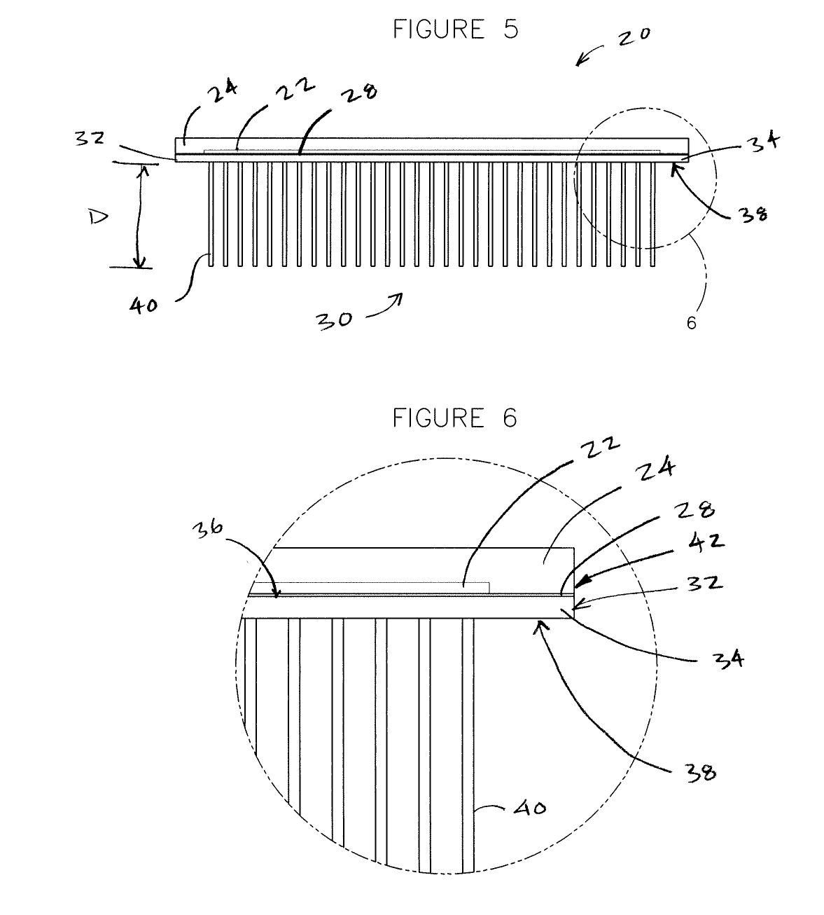

Referring more particularly to FIGS. 3-6, the assembly of the PV solar energy collection panel 22 with an integral or conjoined heat dissipation system 30 having a heat sink 32 is shown according to an exemplary embodiment. The assembly is shown to be arranged in a number of layers. A first layer is shown as an upper (i.e. top, etc.) layer 24 that is environmentally resistive to protect the PV panel 22 and which may be formed from a suitable material such as transparent polymers, glass, ceramics, etc. A second layer is shown as an upper adhesive layer 26 which may be a liquid or solid adhesive, and which may include natural or synthetic resins in single or multi-part configurations, or adhesive sheets, such as ethylene-vinyl acetate (EVA), polycarbonate (PC) and other polymer adhesive films. A third layer is shown as the photovoltaic element layer 22. A fourth layer is shown as a lower adhesive layer 28 (which may include an adhesive such as those described for upper adhesive layer 26). A fifth layer is shown as an upper surface interface 36 of the heat sink 32, which is bonded to the photovoltaic element layer 22 for thermal communication by the lower adhesive layer 28. The layers are arranged with a peripheral ledge portion 42 shown as extending substantially around and projecting outwardly beyond the boundaries of the fins 40. Ledge 42 is intended to provide a structural region which can be coupled to the housing 70 with minimal surface contact in order to minimize the transfer of heat from PV panel 22 to the housing 70 and the components disposed therein. Although specific layers are shown and described according to one exemplary embodiment, certain layers may be rearranged, or omitted entirely, in other embodiments.

The heat dissipation system 30 includes the heat sink 32 which includes a base portion 34 having an upper side defining the upper surface interface 36, and a lower side 38. Heat dissipation system 30 is shown to include a plurality of substantially planar projections (e.g. plates, etc.) which are shown by way of example as fins 40 extending downwardly from lower side 38. According to one embodiment, the thickness of the fins 40 tapers slightly from a first end proximate the heat sink 32, to a second end (e.g. free end) generally opposite the first end. According to one embodiment, the degree of taper of the fins 40 is approximately 0.26 degrees, however, other degrees of taper may be used to suit particular applications. Heat generated in the photovoltaic element layer 22 is transferred through the lower adhesive layer 28 and the upper surface interface 36 and into the base portion 34 of the heat sink 32, and then into the fins 40 of the heat dissipation system 30, which act as a heat exchanger where the heat can then be dissipated passively by natural convection cooling with ambient air, or dissipated actively by forced convection cooling (e.g. by circulating air with a fan, blower or other suitable device, or by circulating a fluid through an enclosed circuit or the like—not shown). According to embodiments where the assembly of the PV panel 22 and heat dissipating system 30 are packaged into the device 10 for use in portable applications, the passive cooling embodiments are generally preferred. However, in alternative embodiments, the assembly of the PV panel and heat dissipating system may be used in stationary applications, wherein the active cooling embodiments are generally preferred. According to any embodiment, each of the layers of the PV panel 22 and the heat dissipating system 30 are arranged and assembled using a suitable manufacturing process such as ambient pressure or vacuum techniques at ambient or elevated temperatures to create an integrally formed, conjoined PV solar collecting panel 22 with a heat dissipating system 30 having a heat sink 32. According to other alternative embodiments, the PV panel and the heat dissipation system may be provided in a scalable manner to provide any particular size and energy capacity for a desired application. For example, the fins may be provided as modular fins that can be readily connected to one another (e.g. in a snap-fit manner or the like) to provide a scalable heat dissipating capability. According to another example, the fins may be provided with internal passages to permit the flow of a separate internal cooling medium therethrough (e.g. such as a liquid or a gas).

According to an alternative embodiment the assembly of the PV panel and heat sink and heat dissipating system may include a sixth layer to modify thermal build-up and change the aesthetic properties of the device. For example, the additional layer may be a sheet or film having reflective properties configured to reflect infrared radiation back through the upper transparent layers. Also, the layer may be colored to change the aesthetic properties or appearance of the assembly, thus improving its integration into its environment or associated product or device.

The assembly of the PV panel and the heat dissipation system may have any of a wide variety of sizes and characteristics. According to one embodiment, the assembly has the following dimensional characteristics, which may be modified to suit any of a wide variety of applications, both stationary and portable. The assembly has a length L within a range of approximately 135.5 mm-137.5 mm, and more particularly within the range of 136.3 mm-136.7 mm, and more particularly is approximately 136.5 mm. The assembly has a width W within a range of approximately 121.5 mm-123.5 mm, and more particularly within the range of 122.3 mm-122.7 mm, and more particularly is approximately 122.5 mm. The assembly has a height H within a range of approximately 33.45 mm-35.45 mm, and more particularly is approximately 34.45 mm. The fins 40 of the heat dissipation system 30 have a depth D within a range of approximately 26.1 mm-30.1 mm, and more particularly within the range of 27.1 mm-29.1 mm, and more particularly is approximately 28.1 mm. The photovoltaic element layer 22 comprises approximately 22 PV cell elements having an electrical output of approximately 6 volts and 2 watts, which may be commercially available as a Motech IS156 cell. According to other embodiments, any suitable number of cell elements having any particular electrical characteristics may be selected to suit a particular application.

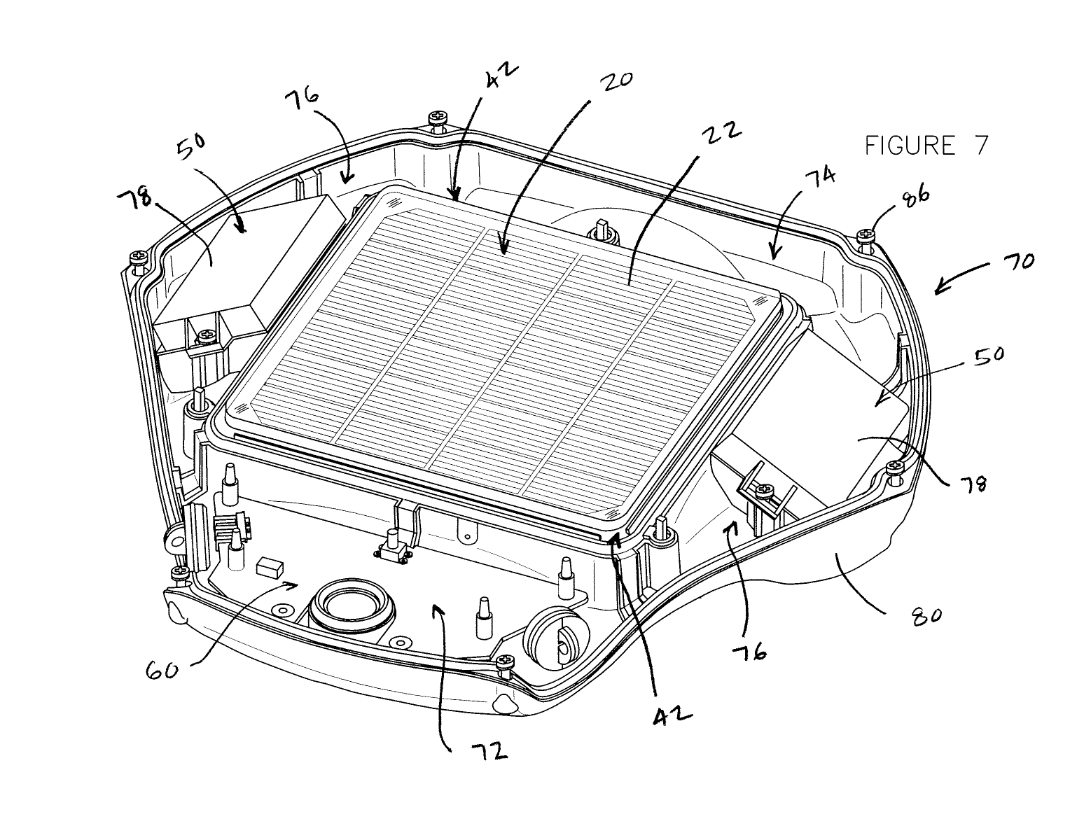

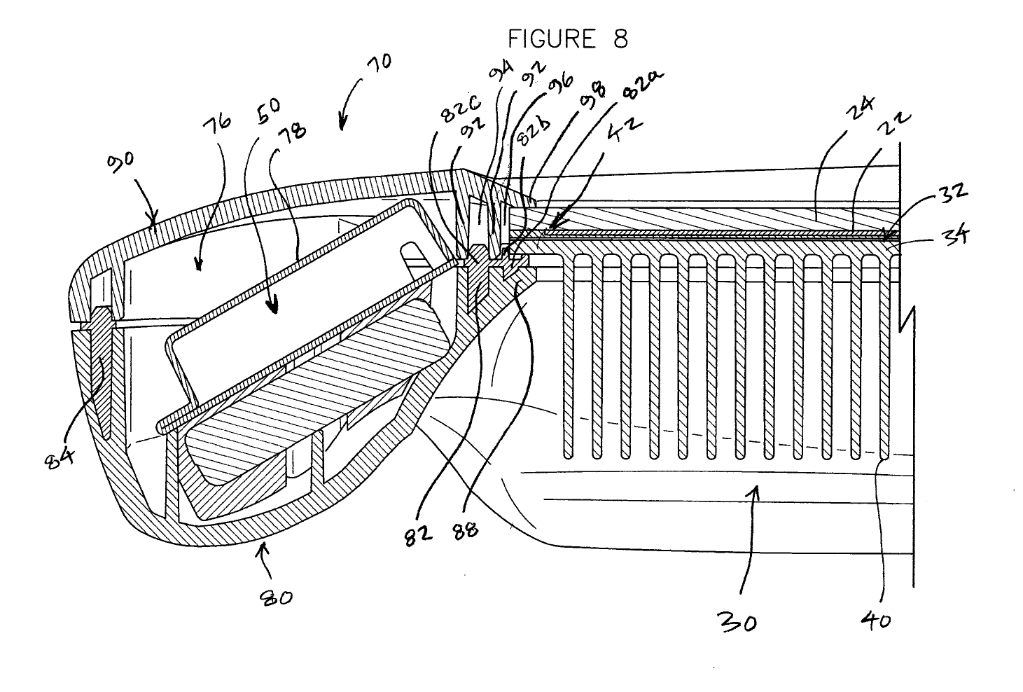

Referring to FIGS. 7 and 8, the assembly of the PV solar energy collection panel 22 and the heat dissipation system 30 are shown disposed within and coupled to housing 70, which has a number of heat management features intended to minimize heat transfer between the solar panel 22 and the energy storage and power supply components of the device 10, according to an exemplary embodiment. Housing 70 includes compartments (e.g. cavities, etc.) shown as a forward compartment 72, a rearward compartment 74 and two laterally disposed side compartments 76. Forward compartment 72 is shown to include components of the power supply system 60 (such as a printed circuit board, wiring, connectors, etc.). Side compartments 76 are shown to include components of the energy storage system 50, including battery containers 78 having an access panel for removably receiving and retaining one or more batteries therein. Rearward compartment 74 may include any of a wide variety of other components that may be useful or desirable in a portable power supply device, such as (but not limited to) cellular modem(s) or other wireless communication devices, RFID devices, GPS devices, etc. (not shown). Each of the compartments is intended to be substantially thermally isolated from the PV panel 22 and heat dissipation system 30 to minimize heating (and potential thermal limiting or thermal-induced shutdown of the energy storage system 50 and/or the power delivery system 60). According to one embodiment, the ledge 42 surrounding the assembly of the PV panel 22 and the heat dissipation system 30 is coupled to the housing 70 in a manner intended to minimize heat transfer to the housing 70 and to the compartments, and thus to the energy storage system 50 and the power supply system 60.

Referring further to FIGS. 7-8, the connection of ledge 42 of the assembly to the housing is intended to substantially minimize heat transfer therethrough by minimizing the surface area contact between the two regions, while still providing a robust mechanical connection and maintaining a watertight seal therebetween. Housing 70 includes a lower portion 80 and an upper portion 90 that may be separated at a substantially horizontally arranged interface therebetween to “sandwich” or otherwise retain or clamp the ledge 42 of the assembly therebetween. Upper housing portion 90 and lower housing portion 80 each define an opening therein (e.g. in the manner of a “donut hole” or the like). Referring to FIG. 8, lower housing portion 80 includes a rim portion 88 that substantially surrounds the opening and is configured to support ledge 42. A peripheral seal 82 is disposed on rim portion 80 and includes a first portion 82a configured to seal against an underside of ledge 42 and a second portion 82b configured to seal against a lateral side of ledge 42 to provide a peripheral watertight seal, a thermal boundary, and a resilient seat that provides a degree of shock absorbency for the PV panel assembly. According to one embodiment, seal 82 provides substantially the only direct contact between lower housing portion 80 and the assembly of the PV panel 22 and heat dissipation system 30. Seal 82 may be formed from a resilient material having good high-temperature life and thermal performance, such as a silicone rubber material, etc. Seal 82 is further shown to include a third portion 82c which serves as a seat for receiving one or more barriers 92 extending downwardly from upper housing portion 90. According to the illustrated embodiment, the interface between barriers 92 and the seal third portion 82c, provides a seal against moisture intrusion between the upper housing portion 90 and the lower housing portion 80 and also forms an insulating peripheral air chamber or air pocket 94 intended to further minimize heat transfer from the PV panel assembly to the compartments 72, 74 and 76. According to other embodiments, the pocket may be filled with a separate thermal insulation material, such as a lightweight, high-temperature resistant foam or the like.

Referring further to FIG. 8, top housing portion 90 includes vertically-oriented ribs 96 spaced about the opening and configured to abut the outer edge (or sides) of ledge 42 to position and stabilize the PV panel assembly within the opening. Upper housing portion 90 is also shown to include a lip 98 that projects over a portion of the top side of ledge 42 (e.g. “overlaps,” etc.) to clamp the ledge 42 against seal portion 82a when the upper housing portion 90 is secured to the lower housing portion 80. Ribs 96 and lip 98 are intended to position and secure the PV panel assembly within the opening in a structurally robust manner that provides limited contact between the upper and lower housing portions 80, 90 and the ledge 42. A second outer seal 84 may be provided adjacent to an outer perimeter of the housing 70 between corresponding structures on the upper and lower housing portions to provide an external moisture seal. Upon placing the PV panel assembly within the opening with the ledge 42 disposed on seal portion 82a, and placing upper housing portion 90 in place with ribs 96 along the outer edge of ledge 42 and with lip 98 overlapping ledge 42, the upper and lower housing portions 80, 90 may be secured to one another to capture the assembly therebetween (e.g. by threaded fasteners 86 or the like in threaded apertures—shown in FIG. 7). Accordingly, the structure and arrangement of the components of the upper and lower housing and seals that robustly secure the PV panel assembly with minimal direct contact and/or that provide thermally-insulating air pockets are intended to provide aspects of a heat management system that minimizes transfer of heat from the PV panel assembly to the compartments 72, 74 and 76 (and the components therein). Such thermal management features may be particularly advantageous when the device is used in environments or applications that have relatively high ambient temperatures (such as equatorial regions of the world), or in close proximity to heat-generating equipment. The ability of the unique features of the heat dissipation system to remove heat from the PV panel, and the heat management system to minimize transfer of heat from the PV panel assembly to the compartments under such circumstances helps improve the performance and capacity of the components of the energy storage system and power delivery system.

According to exemplary embodiments, the housing 70 may be made of a material such as (by way of example) metal (e.g. magnesium, aluminum, steel (including stainless steel), and other metals), plastic, ceramic, composite, polymer (e.g. polycarbonate, polyurethane, polyethylene, polyvinyl chloride, and other polymers and polymer blends), or other suitable material (e.g. graphite fiber and graphite fiber composites, fiberglass, hybrid materials including metal fibers and plastic or polymer), etc.

According to an exemplary embodiment, energy storage system 50 includes a rechargeable battery 52 configured to collect and store the electrical power output from the PV panel 22. Any suitable rechargeable battery may be used, including nickel-cadmium, lithium ion, and other batteries, and any suitable combination of batteries may be used. For example, a rechargeable lithium battery may be used. In some embodiments, a suitable rechargeable lithium battery may be rated at 3.7 V and 1000 mAh (milliamp hours). Battery 52 is packaged within a battery container 54 having an access panel 56 that may be opened (if necessary) for servicing or replacing the battery. The battery container 54 is mounted on the lower housing portion 80 using suitable shock absorbing mounts (e.g. threaded fasteners with resilient pads or washers, etc.).

According to an exemplary embodiment, the power supply system 60 may be provided with the PV panel electrical output and battery electrical output configured in parallel, or may be configured in series, and may be configured in an adjustable manner in which a switch or other element determines the source of electricity provided to an electrical power output element (whether directly from the PV panel, directly from the battery, or from both). Suitable diodes, switches, or other elements may be included in the output circuit to insure that proper electrical characteristics are provided to the electrical power output element.

A suitable connector is provided in electrical contact with the electrical power output element, and is configured to accept a plurality of connector ends so as to mate with various types of external equipment to power that external equipment. External equipment which may be powered by the device include game devices, including game consoles; GPS devices, lights, including flashlights and lamps, including headlamps (e.g., lights that may be worn on the head or attached to a hat or headband); music players (e.g., MP3 players, iPod® devices, etc.); headphones; telephones; cameras; a personal data assistant (PDA) devices; mobile messaging devices; computers; clocks; and other devices. Connectors include (but are not limited to) USB connectors, microphone jacks, connectors for devices from a variety of different manufacturers or models.

According to any preferred embodiment, a portable solar energy collection, storage and power supply device is provided with a PV panel having an integral or conjoined heat sink and heat dissipation system to remove heat from the PV panel. The PV panel and heat sink and heat dissipation system are packaged within a housing having heat management features to minimize heat transfer from the PV panel and heat dissipation assembly to the energy storage and power supply components of the device.

As utilized herein, the terms “approximately,” “about,” “substantially,” and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

It should be noted that the term “exemplary” as used herein to describe various embodiments is intended to indicate that such embodiments are possible examples, representations, and/or illustrations of possible embodiments (and such term is not intended to connote that such embodiments are necessarily extraordinary or superlative examples).

The terms “coupled,” “connected,” and the like as used herein mean the joining of two members directly or indirectly to one another. Such joining may be stationary (e.g., permanent) or moveable (e.g., removable or releasable). Such joining may be achieved with the two members or the two members and any additional intermediate members being integrally formed as a single unitary body with one another or with the two members or the two members and any additional intermediate members being attached to one another.

It should be noted that the orientation of various elements may differ according to other exemplary embodiments, and that such variations are intended to be encompassed by the present disclosure.

It is also important to note that the construction and arrangement of the portable solar energy collection, storage and power supply device as shown in the various exemplary embodiments is illustrative only. Although only a few embodiments of the present inventions have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter disclosed herein. For example, elements shown as integrally formed may be constructed of multiple parts or elements, the position of elements may be reversed or otherwise varied, and the nature or number of discrete elements or positions may be altered or varied. Accordingly, all such modifications are intended to be included within the scope of the present invention as defined in the appended claims. The order or sequence of any process or method steps may be varied or re-sequenced according to alternative embodiments. Other substitutions, modifications, changes and omissions may be made in the design, operating conditions and arrangement of the various exemplary embodiments without departing from the scope of the present inventions.

What is claimed is:

1. A portable solar energy collection, storage and power supply device, comprising:
a housing;
a power supply system disposed at least partially within the housing;
an energy storage system disposed at least partially within the housing and operably coupled to the power supply system;
a solar energy collection and heat dissipation assembly coupled to the housing and operably coupled to one or both of the energy storage system and the power supply system, the solar energy collection and heat dissipation assembly comprising:
an upper transparent layer;
a photovoltaic element layer bonded to the upper transparent layer by an upper adhesive layer;
a heat sink having a base portion with an upper interface surface bonded to the photovoltaic element layer by a lower adhesive layer, the base portion also including a lower heat dissipation surface comprising a plurality of fins.

2. The device of claim 1, wherein the solar energy collection and heat dissipation assembly further comprise a peripheral ledge that is coupled between an upper portion of the housing and a lower portion of the housing.

3. The device of claim 2, wherein the lower portion of the housing includes a sealing surface that provides substantially the only area of contact between the ledge and the lower portion of the housing.

4. The device of claim 3, wherein the upper portion of the housing includes a plurality of ribs that abut an edge of the ledge, and a lip configured to overlap the ledge.

5. The device of claim 4 wherein the upper portion of the housing and the lower portion of the housing are coupled together to clamp the ledge between the sealing surface and the lip.

6. The device of claim 3 wherein the upper portion of the housing include one or more barriers configured to engage the sealing surface to define at least one insulating chamber.

7. The device of claim 1 wherein the solar energy collection and heat dissipation assembly further comprises a power cord extending therefrom and the power cord extends through a watertight seal in one of the upper and lower portions of the housing to the energy storage system.

8. The device of claim 7, wherein the energy storage system comprises one or more batteries disposed within a battery container having an access door, the battery container being secured within a compartment defined within the housing.

9. The device of claim 1, wherein the assembly further comprises a reflective layer configured to reflect IR radiation.

10. The device of claim 9, wherein the reflective layer may be provided in any of a plurality of colors to enhance an aesthetic appearance of the device.

11. The device of claim 1, wherein the upper interface layer of the heat sink is bonded directly to a lower side of the photovoltaic element layer.

12. A solar energy collection and heat dissipation device, comprising:
a housing having an upper portion and a lower portion each having an opening therein, the upper portion having a lip substantially surrounding the opening and the lower portion having a rim substantially surrounding the opening;
an assembly having a photovoltaic element layer bonded to a heat sink with a plurality of fins;
a ledge substantially surrounding the assembly;
wherein the assembly is disposed within the opening with the ledge clamped between the lip and the rim.

13. The device of claim 12 wherein the heat sink is scalable and the plurality of fins are modular and interconnect with one another or to the base.

14. The device of claim 12 further comprising a seal disposed on the sealing edge with a first portion engaging an underside of the ledge, and a second portion engaging an edge of the ledge.

15. The device of claim 12 wherein the housing comprises one or more compartments having at least one electrical component therein, and further comprising a peripheral insulating chamber disposed between the ledge and the compartments.

16. The device of claim 15 wherein the peripheral insulating chamber is an air insulating chamber.

17. A solar energy collection and heat dissipation device, comprising:
an assembly having a photovoltaic element layer bonded to a heat sink with a plurality of fins and having an outer ledge extending therefrom;
a substantially hollow housing defining one or more compartments therein, the housing coupled to the ledge and extending at least partially around a perimeter of the assembly;
an energy storage system disposed within at least one compartment; and
a power supply system disposed within at least one compartment.

18. The device of claim 17 wherein the energy storage system comprises at least one battery in electrical communication with the assembly and the power supply system.
